(19) United States
(12) Patent Application Publication
(10) Pub. No.: US 2003/0062129 A1
(43) Pub. Date: Apr. 3, 2003

(54) Electron-cyclotron resonance plasma reactor with multiple exciters

(76) Inventor: Hao-Jan Ni, Taipei County (TW)

Correspondence Address: BIRCH STEWART KOLASCH & BIRCH, PO BOX 747, FALLS CHURCH, VA, 22040-0747, US

(21) Appl. No.: 10/180,319

(22) Filed: Jun. 27, 2002

(30) Foreign Application Priority Data
Oct. 3, 2001 (TW) 90124356

(51) Int. Cl. C23F 1/00; C23C 16/00

(52) U.S. Cl. 156/345.42; 118/723 MA

(57) ABSTRACT

An Electron-Cyclotron Resonance (ECR) Plasma Reactor with Multiple Exciters is disclosed. The exciters relate to a mechanism that converts the radiation energy to the electron's kinetic energy. With using a suitable antenna distributes the RF energy to distinguished exciter individually, each exciter has its own magnetic coil to build high magnetic field to resonance the electron of the operation gas, ionize the gas and generate high speed electrons. All of the high-speeded electrons can be guided by magnetic flux and accumulated to the remained part of the reaction chamber. There is an auxiliary magnet to cause energized electron moving in a helix path. The helix path makes more chance of the collision between the electron and the process gas. When collision occurs, the electron's kinetic energy activates the process gas and high-density plasma or radicals generated. The auxiliary magnetic field is also used for controlling the uniformity of plasma near the wafer pedestal area. This is a distributed ECR system with multiple RF energy conversion mechanisms, the “exciters”. It simplifies the total system complexity by discrete but simpler main magnets, cooling system, low power RF energy sources etc. The invention gives an easy way to build a large-sized ECR just by increasing the number of exciters.

### BACKGROUND OF THE INVENTION

1. Field of Invention

The invention relates to an Electron-Cyclotron Resonance System and, in particular, to an Electron-Cyclotron Resonance Plasma Reactor with Multiple Exciters.

2. Related Art

Plasma is widely used in semiconductor manufacturing process. Among the plasma generation methods, Electron-Cyclotron Resonance (ECR) is the most potential technology for tomorrow's IC industry. ECR generates a high density, low temperature and high quality plasma. It can operate in very low pressure, e.g. 0.1 m-torr. In such low pressure, the probability of collision between ions is very low, so that the plasma has very good an-isotropic performance, which can make ECR as the best tools for dry etching and other applications as well.

But conventional ECR needs a very complex Main Magnet and cooling system. It is also very difficult to control the uniformity of RF (Radio Frequency) energy pattern, especially for large-sized ECR. Under these limitations, the conventional ECR is hard matching the tomorrow's needs of the semiconductor manufacturing, especially on large-sized wafer.

The theory of operation of ECR being described in the followings:

In the environment of 873 Gauss Magnetic Field, the electron of the Operation Gas (Argon is a typical Operation Gas) spins in a frequency of 2.45 Ghz. For example:

ω=e*B/mₑ

where: ω is the spin rate in rad/sec; e is the electricity of electron; B is the Magnetic Field; mₑ is the mass of electron.

Under the Electrical Field of RF source with same frequency, the electron is resonated and the gas is ionized. 2.45 GHz is an industry standard of RF source, and the ECR is not limited operating in this specified frequency.

When ionization, the radiation energy is converted as the kinetic energy of electron and the kinetic energy of ion. Since the mass of electron is much lower than the mass of the ion of the gas, by the law of the conservation of momentum, velocity change of ion is not significant, most of the radiation energy is converted as the kinetic energy of electron. That is,

mₑ*ΔVₑ=m*ΔVᵢ

since mₑ<<mᵢ then ΔVₑ>>ΔVᵢ

where: mₑ is the mass of electron; mᵢ is the mass of ion; ΔVₑ is the velocity change of electron; ΔVᵢ is the velocity change of ion.

There is an auxiliary magnet to cause energized electron moving in a helix path and the radius (rₕ) of the helix is

rₕ=mₑ*V⊥/(e*B)

where mₑ is the mass of electron; V⊥ is the velocity of electron perpendicular component to the magnetic field B; e is the electricity of electron; B is the magnetic field. Magnetic flux is moving forward to the bottom of the reaction chamber by diffusion. The helix path makes more chance of collisions between electron and Reactant or Process Gas. When collision occurs, the electron's kinetic energy activates the process gas to be ions or radicals, and the high-density plasma generated.

The auxiliary magnetic field guides the motion of energized electron and the ions, so that the uniformity of the magnetic flux can be used for controlling the uniformity of plasma near the wafer pedestal area.

The Conventional ECR has a centralized big RF energy conversing cavity, which is located on the top of the Reaction Chamber. The coil of the Main Magnet is set around the chamber. The length of the ring of the coil increases with the periphery of the chamber. The height of the coil increases with the radius of the chamber. The length and the height of the coil sustain a suitable ratio for generating a uniform magnetic field. The depth of the layer of the RF energy conversion is just few millimeters (mm). With respect to this depth, the cross section area of Main Magnet covered is much larger. Considering large area coverage with 873 Gauss high intensity and unformed Magnetic Field, it needs a very complex Main Magnet to build such magnetic field, but its useful working layer is just few millimeters. The Main Magnet of Conventional ECR is inefficient. By the way, the cooling system for the complex Main Magnet, the centralized high-powered RF source, and the pattern of the RF energy control with large area limit the applications of Conventional ECR on large wafer size.

The typical configuration of Conventional ECR system is shown in FIG. 1. The Wafer (134) is fixed on the top of the Wafer Pedestal (135). All of them are placed in a Vacuum Reaction Chamber (131). The ECR system operates in very low pressure by a Vacuum Pump (133). The plural reactant gas (132) is introduced into the Vacuum Reaction Chamber (131).

Through Dielectric Window (117), the Antenna (115) feeds the energy of the Radiation Source (111) to the top of the Vacuum Reaction Chamber (131). The Impedance and Transmission Unit (114) of RF source should be carefully controlled. The top section (122) of the Vacuum Reaction Chamber (131) is used to convert the RF energy to kinetic energy of electron.

Surrounding the top section (122) of the Vacuum Reaction Chamber (131), there is the Main Magnet (121) which builds an 873 Gauss high Magnetic Field. In such Magnetic Field, the electron of the Operation Gas (132) spins in a frequency of 2.45 Ghz. Under the Electrical Field of RF source with same frequency, the electron is resonated and the gas is ionized. Since the mass of electron is much lower than the mass of the ion of the gas, according to the law of the conservation of momentum, most of the radiation energy is converted as the kinetic energy of electron when ionization. Therefore, the velocity or the energy change of the ion is not significant.

Surrounding the remained section (139) of the Vacuum Reaction Chamber (131), there is a set of Auxiliary Magnets (123). The magnetic field intensity of the remained section (139) is only few fraction of field intensity in the top section (122). Therefore, the Auxiliary Magnets (123) is simpler than the Main Magnet (121), it should be implemented by a set of small Electrical Magnets or a set of Permanent Magnets.

The Magnetic Flux (124) causes the energized electron moving in a helix path (125) with following the Magnetic Flux (124) and moving forward to the Wafer Pedestal (135) in the Vacuum Reaction Chamber (131) by diffusion. It makes more chance of collisions between electron and reactant Gas (132). When collision occurs, the electron's kinetic energy activates the reactant gas to be ions or radicals, and the high-density plasma generated.

The Magnetic Flux (124) of the Auxiliary Magnet (123) is also used for controlling the Uniformity of plasma near the Wafer (134) and Wafer Pedestal (135) area.

Different manufacturing process can be formulated by the different operation pressure of the Vacuum Reaction Chamber (131), Reactant Gas (132), flow rate, Bias (136) on the Wafer Pedestal (135) etc., and all of them are controlled by a process controller (137).

### SUMMARY OF THE INVENTION

Functionally, the Reaction Chamber of ECR (Electron-Cyclotron Resonance) is divided into two parts. The first part is the area that converts the RF energy to kinetic energy of electron, which is called “Radiation Energy Coupling Cavity (RECC)” in the invention. Another part of Vacuum Reaction Chamber is used for activating the process gas by the energized electron to form plasma or radicals, and controlling the uniformity of plasma as well. This section of the Reaction Chamber is called “Plasma/Radical Generating and Diffusing Section” or “PRGD” in the invention.

The invention proposes a method of ECR system with multiple exciters. Each exciter is a RECC. Each RECC has its own magnetic coil to build high magnetic field to resonance and ionize the electron of the operation gas. The multiple RECCs are used to solve the difficulty of the conventional ECR using a centralized and large-sized RF energy conversing cavity, especially on the applications of large wafer size.

The energized electron from all of the RECC are guided by magnetic flux and accumulated to the PRGD section of the Reaction Chamber. There is a set of auxiliary magnets around the PRGD section. Its flux causes the energized electron moving in a helix path with following the Magnetic Flux and moving forward to the Wafer Pedestal in the Reaction Chamber by diffusion. Electrons moving in a helix have a greater opportunity to hit the particles of the process gas and generate high-density plasma or radicals. The auxiliary magnetic field is also used for controlling the uniformity of plasma near the wafer pedestal area.

The total high-Magnetic-Field area of the distributed RECC system is near one quarter of the area of the Reaction Chamber. The half of the interval of each of the distributed RECC (that is, one quarter of the area of the Reaction Chamber) is used as the cavity of the RECC. The periphery of the cavity is used for setting the Main Magnet and left a suitable space for other usage. The total operation area of Main Magnet of all RECC is one quarter of the chamber size, which is the area of the Main Magnet of the conventional ECS. Consequently, the Main Magnet has the suitable height and radius to maintain the uniformity of the magnetic field inside the cavity. Comparing with the volume of the Main Magnets between the invention and the prior art, the invention has a smaller size. Therefore, the total power required and total heat disposed of the new system is lower, and there is more space to send the heat out even though the number of the RECC is plenty. The diameter of the Main Magnet of each RECC is much smaller than the chamber's diameter, which is the diameter of the main magnet of the conventional ECS. Therefore, the Main Magnet of each RECC has better efficient and is implemented in a simpler way, which is using a coil with more number of turns but lower current to get enough Ampere-Turn building the 873 Gauss Magnetic Field in each RECC.

While the RF energy source should be supplied by a set of Low Power Generators, low power RF amplifiers or Oscillators. It is simpler than the big and centralized RF source used in the conventional ECR.

The distributed RECC highly simplifies the total system complexity. Most important of all, the invention gives an easy way to build a large-sized ECR by increasing the number of RECC, RF sources, and Antennas.

The invention will become more fully understood from the detailed description given herein below illustration only, and thus are not limitation of the present invention, and wherein:

### BRIEF DESCRIPTION OF THE DRAWINGS

FIG. 1 is a block diagram of conventional ECR system;

FIG. 2 is a block diagram of slot antenna system;

FIG. 3 is a cross-sectional view of the ECR plasma system with multiple exciters;

FIG. 4 is an enlarged diagram of exciters in FIG. 3;

FIG. 5 is a top view of the radiation energy coupling cavity in detail;

FIG. 6 is an enlarged diagram of FIG. 5; and

FIG. 7 is a feasible configuration of a large-sized ECR.

### DETAILED DESCRIPTION OF THE INVENTION

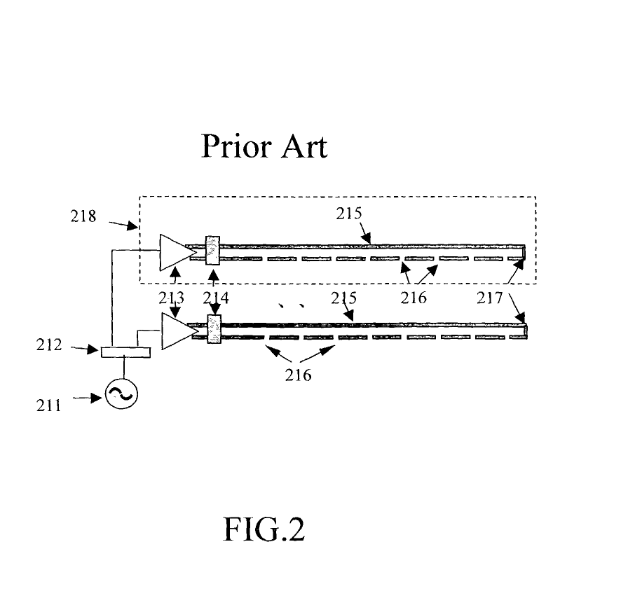

How to feed high-powered RF energy is one of the key issues on ECR design. The invention proposes an ECR system with multiple exciters (the RF energy to the kinetic energy of electron conversion mechanisms). It is a distributed system. How to feed RF energy to multiple points effectively is the useful background information for the invention. Using a set of individual Antenna is a typical way and the Slot Antenna is another. The Slot Antenna is a mature technology and widely used in today's radar applications. A typical Slot Antenna System is shown in FIG. 2.

Referring FIG. 2, the Signal of Radiation Source (21 1) is divided by a Power Divider (212) and distributed to each Slot Antenna unit (218). With using individual RF Power Amplifier or Oscillator (213) of each of the Slot Antenna unit (218), the RF energy is coupled to the Slot Antenna (215) through the Transmission and Impedance Match (214).

The Slot Antenna (215) is a wave-guide device with short-circuit terminator (217) to form a standing wave in the cavity. In each of wavelength (near 12 cm for 2.45 GHz Microwave) from the termination (217), there are Nodes of the standing wave, and between the Nodes, there are Anti-nodes. The slots (216) cut in the positions of each Anti-nodes, the RF energy should be send out and feed the RF energy to the points of every wave-length. The Slot Antenna (215) is simple equipment to feed the RF energy to multiple points.

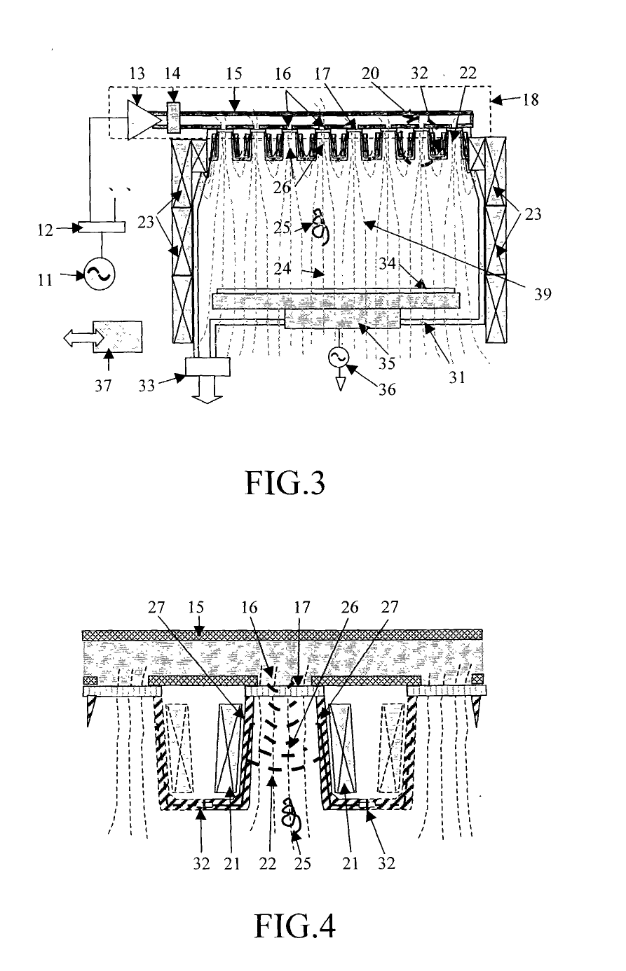

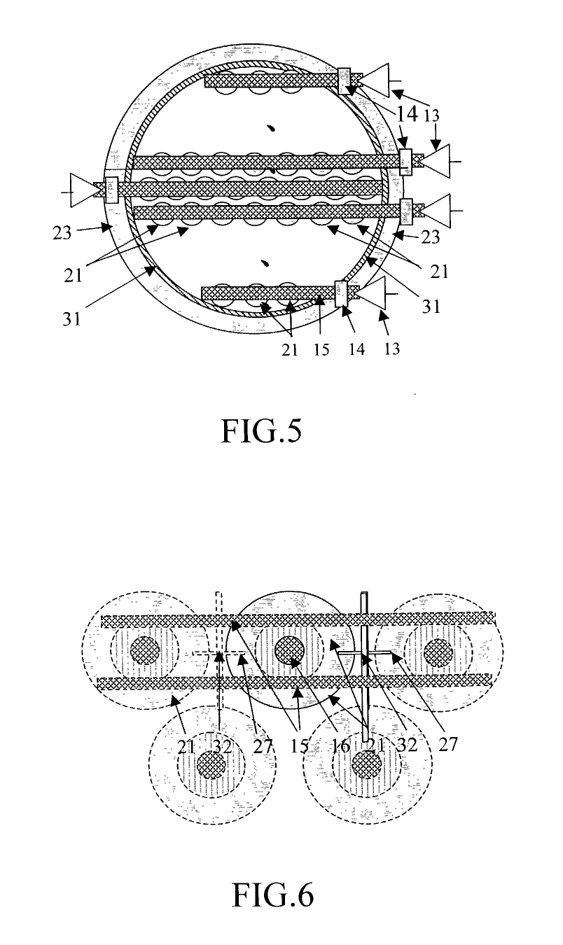

The Preferred Embodiments are shown in FIG. 3 to FIG. 6. The following details are used the same element number in those figures.

Referring to FIGS. 3 to 6, the Wafer (34) is fixed on the top of the Wafer Pedestal (35). All of them are placed in a Reaction Chamber (31). The Reaction Chamber (31) maintains in very low pressure by a Vacuum Pump (33) from its outlet. The Wafer Pedestal (35) is set at the bottom of the Reaction Chamber and is adjustable for modifying the distance between the wafer (34) and the top of the Reaction Chamber (31), and for controlling ion density or energy near the wafer (34).

The plural reactant gas (27, 32) is introduced into the Reaction Chamber (31). Each of them comprises a valve apparatus for individually supplying gas and controlling gas flow rates individually. Functionally, There are two kinds of gas, one is the Operation Gas (27), i. e. Argon, and the others are the Process Gas (32). The Operation Gas (27) is used in each RECC (22) to generate high-speed electrons, while the plural Process Gas (32) is the Reactant Gas to form plasma or radicals for wafer manufacturing.

The Signal of Radiation Source (11) is divided by a Power Divider (12) and distributed to each Slot Antenna unit (18). With using an individual RF Power Amplifier or Oscillator (13) in each of the unit (18), the energy is coupled to the Slot Antenna (15) through Transmission and Impedance Match circuits (14).

Through the slots (16) of each Slot Antenna (15), the RF energy is feed to the RECC (22) paired with the slots. Each RECC (22) has is a Dielectric Window (17) to seal the Reaction Chamber (31) maintaining the vacuum condition.

The RECC (22) is arranged in an array covering full area of Reaction Chamber. Each wavelength of Radiation Source (11) apart and arranged in hexagonal shape should be a typical case. For 2.45 GHz Microwave RF Source, the neighboring RECC is near 12 cm apart, and the diameter of the cavity of RECC (22) is near 6 cm for example. Each of RECC (22) has its owned Main Magnet (21) with suitable Ampere-Turn, to build 873 Gauss high intensity Magnetic Field in the cavity of RECC locally and increasing the usage efficiency of Main Magnet (21).

In each RECC, the Magnetic Field and RF energy is built to resonate and ionize the electron of the Operation Gas (27), then the high-speed electron is generated. The energized electron from all RECC are guided by the magnetic flux (24) and accumulated to the PRGD Section (39) of the Reaction Chamber (31).

The total high-Magnetic-Field area of the distributed RECC (26) is near one quarter of the area of the Reaction Chamber (31) or the coverage of the conventional ECS. Moreover, comparing with the volume of the Main Magnets, there are more difference. The total power required and total heat disposed of the new system is lower, and also has more space to send the heat out. The Main Magnet (21) of each RECC (22) covers a small area. It can be implemented by a simple way, i.e. using a coil with more number of turns but lower current to get enough Ampere-Turn building the 873 Gauss Magnetic Field required. The Main Magnet (21) of each RECC (22) can have higher efficiency.

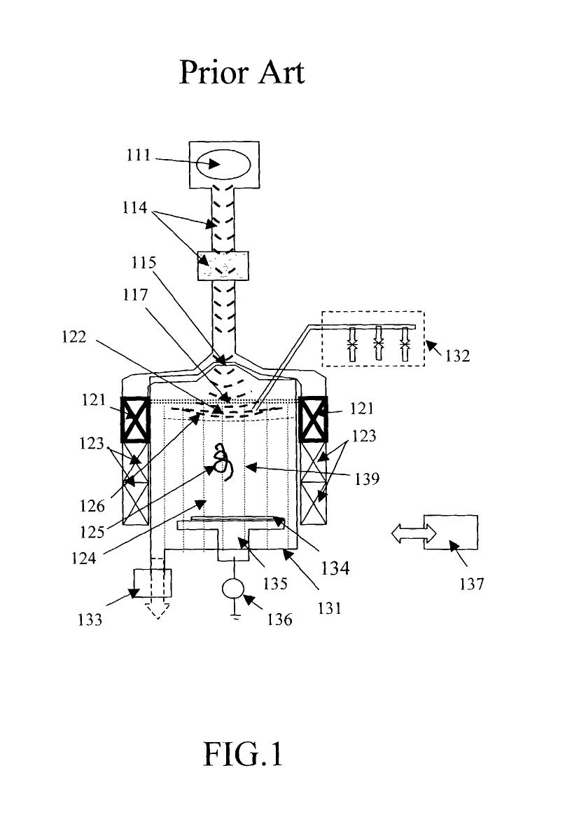

While the RF energy source should be supplied by a set of Low Power Radiation Sources (11), low power RF amplifiers or Oscillators (13). It is simpler than the centralized and big RF source (111) of the conventional ECR in FIG. 1.

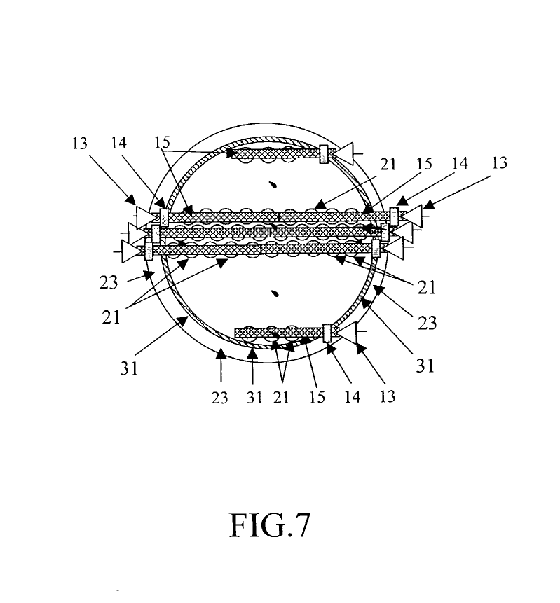

The distributed RECC (22) highly simplifies the total system complexity. Most importantly, the invention gives an easy way for large-sized ECR just by increasing the number of RF source (13), Antenna(15) and RECC (22). The concept is shown in FIG. 7.

Referring to FIG. 3 to FIG. 7, surrounding the PRGD Section (39) of the Reaction Chamber (31), there is a set of Auxiliary Magnets (23). The magnetic field intensity of the PRGD Section (39) is only few fraction of field intensity in the RECC (22) section. Therefore, the Auxiliary Magnet (23) is simpler than the Main Magnet (21), it should be implemented by a set of small Electrical Magnets or a set of Permanent Magnets.

The Magnetic Flux (24) in the PRGD Section (39) causes the energized electron moving in a helix path (25) with following the Magnetic Flux (24) and moving forward to the Wafer Pedestal (35) in the Reaction Chamber (31) by diffusion. The helix path (25) makes more chance of collisions between electron and Process Gas (32). When collision occurs, the electron's kinetic energy activates the Reactant Gas (32) to be ions or radicals, and the high-density plasma generated.

The Magnetic Flux (24) of the Auxiliary Magnet (23) is also used to control the Uniformity of plasma near the Wafer (34) and Wafer Pedestal (35) area.

Different manufacturing process can be formulated by different operation pressure of the Chamber (31), types and flow rate of the Operation Gas (27) or the Process Gas (32), the Bias (36) on the Wafer Pedestal (35) etc., and all of them are controlled by a process controller (37).

The path length of the energized electron in the PRGD Section (39) determines the height of the Reaction Chamber (31). The depth of PRGD Section (39) required is considered for the uniformity controlling of plasma near the Wafer Pedestal (35) area, it depends on the size of RECC (22) rather the size of the Reaction Chamber (31). Therefore, the height of Reaction Chamber (31) of the invention should be lower than the height of the conventional ECR, especially on the equipment for larger wafer size.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. An electron-cyclotron resonance (ECR) plasma reactor with multiple exciters, comprising:
a vacuum chamber, which forms a diffusing (PRGD) section and has a outlet for maintaining a low pressure state by a vacuum pump;
a plurality of process gas source, for furnishing at least a reactant gas into said vacuum chamber;
a plurality of radiation energy coupling cavity (RECC) installed in the top of said vacuum chamber, each of said RECC including a plurality of main magnet and a radiation energy supply which resonated the electron and ionized the said operation gas;
a plasma/radical generating section, connecting the plurality of RECC to form said multiple exciters which convert radiation energy to electron's kinetic energy and generate energized electrons, said energized electrons are guided and accumulated to said PRGD section of said chamber by the plurality of RECC;
a wafer pedestal, installed in the bottom of the vacuum chamber, for holding a wafer in said vacuum chamber and accepting the ionized reactant gas; and
a plurality of auxiliary magnet, surrounding said PRGD section of said chamber to generate magnetic flux, for guiding the energized electron and moving in helix path to increase the chance of collisions between said energized electron and said process gas and for controlling the uniformity of plasma to near of said wafer pedestal, said energized electron activating said process gas and more plasma or radicals generated when collision.

2. The plasma reactor of claim 1, wherein said radiation energy supply including a plurality of radiation energy sources, amplifiers, oscillators, power divider, transmission, impedance match device, antenna and dielectric window for supplying the radiation energy to each of said RECC.

3. The plasma reactor of claim 1, further comprising plural sensors, plural devices and a process controller for monitoring, adjusting or controlling the operation of said reactor.

4. The plasma reactor of claim 1, wherein the plurality of process gas source further including a valve apparatus, for individually supplying gas and controlling gas flow rates individually.

5. The plasma reactor of claim 1, further comprising a bias RF power source coupled to said wafer pedestal for controlling ion energy near said wafer.

6. The plasma reactor of claim 1, wherein the wafer pedestal is adjustable for modifying the distance between said wafer and said RECC for controlling ion density or energy near said wafer.

7. The plasma reactor of claim 1, wherein the wafer is selected from the group consisting of semiconductor wafer, substratum of plane display and substratum of semiconductor applications.

8. The plasma reactor of claim 1, wherein the plurality of RECC providing an array covering full cross section area of said vacuum chamber, each wavelength of said radiation source apart and arranged in hexagonal shape being a typical case.

9. The plasma reactor of claim 1, wherein each of said RECC including a dielectric window for sealing said chamber and passing said RF energy, dielectric material of the type including quartz or sapphire.

10. The plasma reactor of claim 1, wherein each of said RECC comprising said antenna, the type of antenna including individual horn or slot antenna.

11. The plasma reactor of claim 1, wherein said main magnet or auxiliary magnet, type of both said magnet including an electrical magnet or a permanent magnet.

12. The plasma reactor of claim 1, wherein the radiation energy supply and the RECC operating form low frequency to microwave band.

13. The plasma reactor of claim 1, wherein the type of the radiation energy supply is selected from the group consisting of tube and solid-state device.
